(19) United States
(12) Patent Application Publication
(10) Pub. No.: US 2007/0218213 A1
(43) Pub. Date: Sep. 20, 2007

(54) METHOD OF MANUFACTURING LIQUID CRYSTAL ALIGNMENT FILM

(76) Inventors: Chih-Chien Chou, Taipei County (TW); Fu-Kuo Ou, Hsinchu City (TW); Yi-Tyng Wu, Chiayi City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,235

(22) Filed: Mar. 14, 2006

(51) Int. Cl. C23C 16/00; C23C 14/00

(52) U.S. Cl. 427/523; 427/248.1

(57) ABSTRACT

A method of manufacturing liquid crystal alignment film includes performing an ion implantation process after providing a layer of organic or inorganic material on a substrate for performing an alignment treatment on the layer of organic or inorganic material is provided. Since the alignment treatment is a kind of non-contact method, it can lower the probability of damaging the organic alignment film and prevent generating powders and particles. Furthermore, the layer of inorganic material is formed on the substrate prior to the alignment treatment, so the inorganic material layer can be patterned before the alignment treatment.

### BACKGROUND OF THE INVENTION

1. Field of the Invention

The present invention relates to a method of manufacturing a liquid crystal display component, and more particularly, to a method of manufacturing a liquid crystal (LC) alignment film.

2. Description of the Related Art

Along with continuous development of high technology, video products, particularly digital video or image devices, have become very popular in our daily life. Inside the digital video or image device, the display unit is an important component for displaying the related information, such that the user can read information from the display and further control the operation of the device.

Since the liquid crystal display (LCD) is advantageous in the characteristics of low voltage operation, no radiation, light weight and small size, it has become the main stream in the display development. The alignment film disposed between the liquid crystal and the transparent electrode inside the LCD is a key component for controlling the display quality, and its major purpose is to align the molecules of the liquid crystal before the electric field is applied thereon.

The general alignment film is made of an organic material, and an alignment treatment is performed on the surface of the organic material by using a contact type rubbing process with a flannelette roller. However, the contact type alignment treatment often damages the alignment film and generates powders and particles.

Accordingly, a method of using the inorganic material as the alignment film has been developed recently. The manufacturing process includes depositing the inorganic material on the substrate with a specific angle under an extreme vacuum condition, in which the incline angle and density of the deposit layer are controllable. However, the patterning process cannot be performed on such inorganic alignment film after it is formed on the substrate, which significantly restricts its application.

### SUMMARY OF THE INVENTION

Therefore, it is an object of the present invention to provide a method of manufacturing a liquid crystal alignment film. This method prevents the powders and particles from being generated on the organic alignment film.

It is another object of the present invention to provide a method of manufacturing a liquid crystal alignment film. In the method, a patterning process can be performed on the inorganic alignment film, such that the margins of the inorganic alignment film design are increased.

The present invention provides a method of manufacturing a liquid crystal alignment film, the method comprises providing a material on a substrate, and performing an alignment treatment on the material layer by using an ion implantation process.

In the method of manufacturing a liquid crystal alignment film according to a preferred embodiment of the present invention, the ion implantation process mentioned above comprises using a chemical element with valence of 3 or 5 such as B (boron), P (phosphorus), As (arsenic), or Sb (antimony). In addition, the implanting angle of the ion implantation process is about 0˜75 degrees.

In the method of manufacturing a liquid crystal alignment film according to the preferred embodiment of the present invention, after forming the material layer on the substrate and before performing the ion implantation process, the method further comprises etching back the material layer in order to control the thickness of the material layer.

In the method of manufacturing a liquid crystal alignment film according to the preferred embodiment of the present invention, the step of providing the material layer on the substrate comprises coating a layer of alignment material on the substrate by using a spin coating, a slit coating, or a spin on dielectric (SOD) coating method and then performing a baking process thereon. Wherein, the alignment material mentioned above comprises HSQ, MSQ, SiO₂ or TiO₂ solution.

In the method of manufacturing a liquid crystal alignment film according to the preferred embodiment of the present invention, the step of providing the material layer on the substrate comprises forming a layer of alignment material on the substrate by using a printing method. Wherein, the material of the alignment material layer comprises the polyimide (PI) and polyamide (PA) family.

In the method of manufacturing a liquid crystal alignment film according to the preferred embodiment of the present invention, the step of providing the material layer on the substrate comprises depositing an alignment material layer on the substrate. Wherein, the method for depositing the alignment material layer comprises a sputtering process, an evaporation process, a CVD (Chemical Vapor Deposition) process or a PE-CVD (Plasma Enhanced-Chemical Vapor Deposition) process. In addition, the alignment material layer comprises an oxide.

The present invention further provides a method of manufacturing a liquid crystal alignment film. The method comprises forming a material layer on the substrate, and patterning the material layer to form a patterned material layer. Then, an alignment treatment is performed on the patterned material layer by using an ion implantation process.

In the method of manufacturing a liquid crystal alignment film according to a preferred embodiment of the present invention, the ion implantation process mentioned above comprises using a chemical element with valence of 3 or 5 such as B (boron), P (phosphorus), As (arsenic), or Sb (antimony). In addition, the implanting angle of the ion implantation process is about 0˜75 degrees.

In the method of manufacturing a liquid crystal alignment film according to the preferred embodiment of the present invention, after patterning the material layer and before performing the ion implantation process, the method further comprises etching back the patterned material layer in order to control the thickness of the patterned material layer.

In the method of manufacturing a liquid crystal alignment film according to the preferred embodiment of the present invention, the step of patterning the material layer comprises performing a photoresist coating process, an exposure process, a development process, an etching process and a stripping process.

In the method of manufacturing a liquid crystal alignment film according to the preferred embodiment of the present invention, the step of forming the material layer on the substrate comprises coating a layer of alignment material by using a spin coating, a slit coating, or a spin on dielectric (SOD) coating method and then performing a baking process thereon. Wherein, the alignment material mentioned above comprises HSQ, MSQ, SiO₂ or TiO₂ solution.

In the method of manufacturing a liquid crystal alignment film according to the preferred embodiment of the present invention, the step of providing the material layer on the substrate comprises depositing an alignment material layer on the substrate. Wherein, the method for depositing the alignment material layer comprises a sputtering process, an evaporation process, a CVD (Chemical Vapor Deposition) process, or a PE-CVD (Plasma Enhanced-Chemical Vapor Deposition) process. In addition, the alignment material layer comprises an oxide.

Since the present invention adopts a non-contact type alignment method (i.e. the ion implantation process), the probability of the alignment film damage is reduced and the powders and particles will not be generated thereon. In addition, since the alignment treatment is performed after the inorganic material layer is formed in the present embodiment, by applying the patterning process that is performed before the alignment treatment, the margins of the inorganic alignment film design are increased.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 schematically shows a flow chart illustrating a method of manufacturing a liquid crystal alignment film according to a first embodiment of the present invention.

FIG. 2 schematically shows a flow chart illustrating a method of manufacturing a liquid crystal alignment film according to a second embodiment of the present invention.

FIG. 3 schematically shows a flow chart illustrating a method of manufacturing a liquid crystal alignment film according to a third embodiment of the present invention.

### DESCRIPTION OF THE PREFERRED EMBODIMENTS

The main concept of the present invention includes first providing a material layer on the substrate, and then performing an alignment treatment on the material layer by using an ion implantation process so as to complete the whole manufacturing process of the liquid crystal alignment film. In addition, the alignment film formed in the present invention can be applied in the liquid crystal display devices such as the TFT-LCD (thin film transistor liquid crystal display) display, the HTPS (high temperature poly-silicon) display or the LCOS (liquid crystal on silicon) display. Even though, the present invention is not limited by it. A number of embodiments are proposed in the present invention hereinafter to describe the application of the present invention; however, the present invention should not be limited by them.

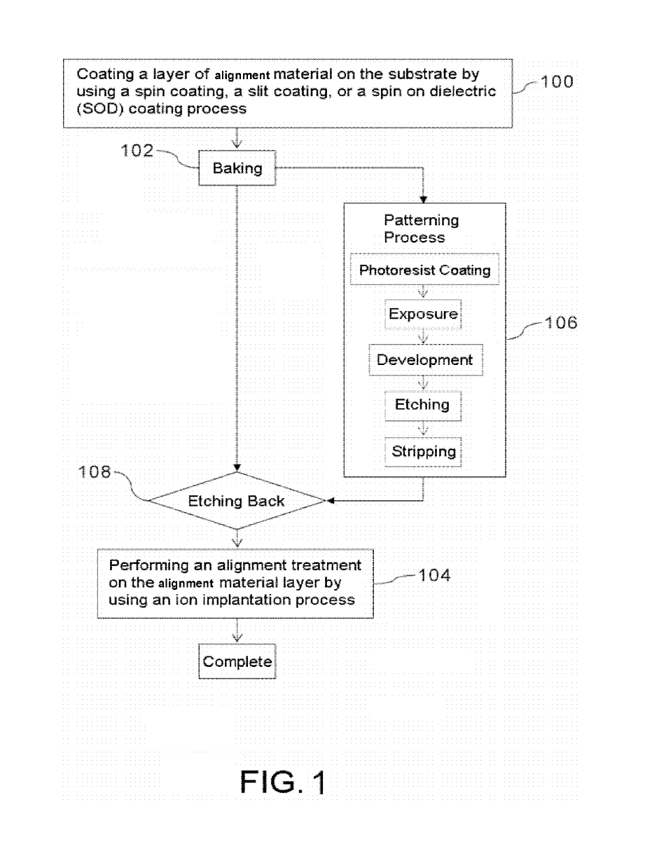

FIG. 1 schematically shows a flow chart illustrating a method of manufacturing a liquid crystal alignment film according to a first embodiment of the present invention.

Referring to FIG. 1, first in step 100, a layer of alignment material is coated on the substrate by using a spin coating, a slit coating or a spin on dielectric (SOD) coating process. Wherein, the alignment material comprises the HSQ, MSQ, SiO₂ or TiO₂ solution. Since the liquid alignment material solution has better filling capability, the liquid can be used to flatten the layer.

Then, in step 102, a baking process is performed on the alignment material layer so as to evaporate the resolution inside the alignment material for forming an dielectric material layer. In step 104, an alignment treatment is performed on the alignment material layer by using an ion implantation process. Wherein, the ion implantation process is performed by a chemical element with valence of 3 or 5. For example, the ion implantation process mentioned above may be performed by using a chemical element such as B (boron), P (phosphorus), As (arsenic) or Sb (antimony). In addition, the implanting angle of the ion implantation process for performing the alignment treatment is about 0˜75 degrees.

Referring to FIG. 1, if it is required to form a patterned alignment film, a step 106 is added between step 102 and step 104. Specifically, step 106 is a patterning process to pattern the alignment material layer in order to form a pattered material layer. Wherein, the patterning process comprises performing a photoresist coating process, an exposure process, a development process, an etching process and a stripping process.

Moreover, a step 108 is further performed between step 102 and step 104 or between step 102 and step 106, wherein the step 108 is an etching back process (to etch the alignment material layer), such that the alignment material layer can be deposited to a certain thickness.

Since the present invention adopts a non-contact type alignment method (i.e. the ion implantation process), the probability of the alignment film damage is reduced and the powders and particles generated thereon are prevented.

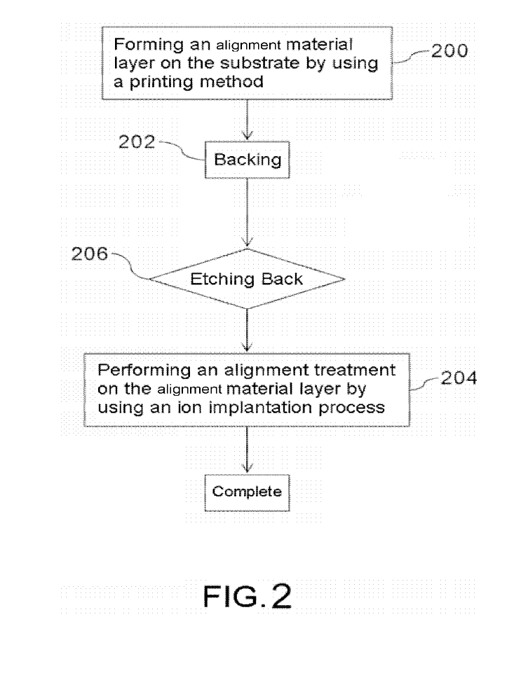

FIG. 2 schematically shows a flow chart illustrating a method of manufacturing a liquid crystal alignment film according to a second embodiment of the present invention.

Referring to FIG. 2, in step 200, an alignment material layer is formed on the substrate by a printing process such as a relief printing process. Wherein, the material of the alignment material layer comprises the polyimide (PI) and polyamide (PA) family. Since the printing process is used, if it is required to form a patterned alignment film, the patterned alignment material layer can be formed directly in this step. Then, in step 202, a baking process is performed to remove the resolution inside the alignment material layer.

Then, in step 204, an alignment treatment is performed on the alignment material layer by using an ion implantation process. Wherein, the ion implantation process is performed by a chemical element with valence of 3 or 5. For example, the ion implantation process mentioned above may be performed by using a chemical element such as B (boron), P (phosphorus), As (arsenic) or Sb (antimony). In addition, the implanting angle of the ion implantation process for performing the alignment treatment is about 0˜75 degrees.

Moreover, a step 206 is further performed between step 202 and step 204, wherein step 206 is an etching back process (to etch the alignment material layer), such that the alignment material layer can be deposited to a certain thickness.

Since the present invention adopts a non-contact type alignment method (i.e. the ion implantation process), the probability of the alignment film damage due to the alignment treatment is reduced and the powders and particles will not be generated thereon.

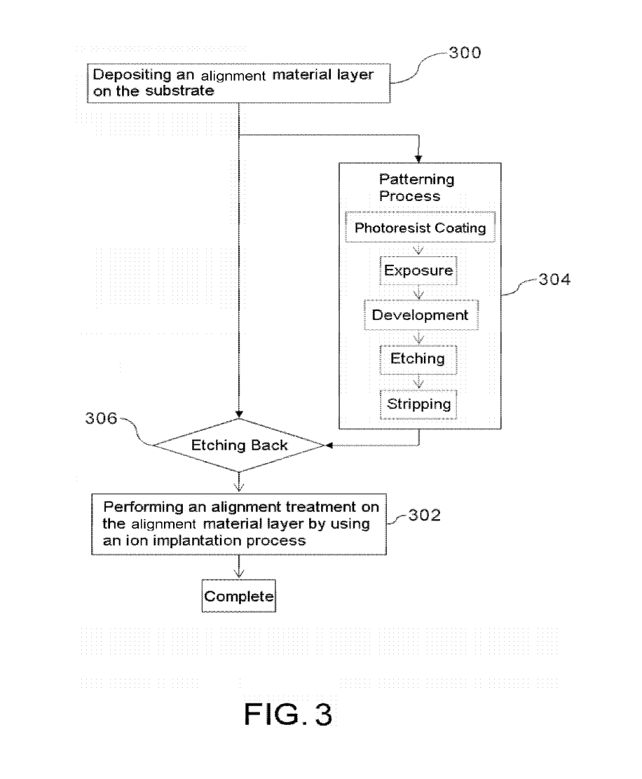

FIG. 3 schematically shows a flow chart illustrating a method of manufacturing a liquid crystal alignment film according to a third embodiment of the present invention.

Referring to FIG. 3, in step 300, an alignment material layer is deposited on the substrate, and the method for depositing the alignment material layer comprises a sputtering process, an evaporation process, a CVD (Chemical Vapor Deposition) process or a PE-CVD (Plasma Enhanced-Chemical Vapor Deposition) process. With such process, a nonalignment film is formed on the substrate. Wherein, the alignment material layer comprises an oxide or other appropriate material layer.

Then, in step 302, an alignment treatment is performed on the alignment material layer by using an ion implantation process. Wherein, the ion implantation process is performed by a chemical element with valence of 3 or 5. For example, the ion implantation process mentioned above may be performed by using a chemical element such as B (boron), P (phosphorus), As (arsenic) or Sb (antimony). In addition, the implanting angle of the ion implantation process for performing the alignment treatment is about 0˜75 degrees.

Furthermore, if it is required to form a patterned alignment film, a step 304 is added between step 300 and step 302. Specifically, step 304 is a patterning process for patterning the alignment material layer in order to form a pattered material layer. Wherein, the patterning process comprises performing a photoresist coating process, an exposure process, a development process, an etching process and a stripping process.

Moreover, a step 306 is further performed between step 300 and step 302 or between step 304 and step 302, wherein step 306 is an etching back process (to etch the organic material layer), such that the organic material layer can be deposited to a certain thickness.

Since the alignment treatment is performed after the inorganic alignment material layer is formed in the present embodiment, by applying the patterning process that is performed before the alignment treatment, the margins of the inorganic alignment film design are increased.

In summary, in the method of the present invention, an alignment treatment is performed on the material layer by using the ion implantation process. Accordingly, the present invention does not only avoid the organic alignment film damage but also increases the margins of the inorganic alignment film design.

Although the invention has been described with reference to a particular embodiment thereof, it will be apparent to one of the ordinary skills in the art that modifications to the described embodiment may be made without departing from the spirit of the invention. Accordingly, the scope of the invention will be defined by the attached claims not by the above detailed description.

What is claimed is:

1. A method of manufacturing a liquid crystal alignment film, comprising:
providing a material layer on a substrate; and
performing an alignment treatment on the material layer by using an ion implantation process.

2. The method of manufacturing the liquid crystal alignment film of claim 1, wherein the ion implantation process comprises using a chemical element with valence of 3 or 5.

3. The method of manufacturing the liquid crystal alignment film of claim 1, wherein the ion implantation process comprises using a chemical element such as B (boron), P (phosphorus), As (arsenic) or Sb (antimony).

4. The method of manufacturing the liquid crystal alignment film of claim 1, wherein the implanting angle of the ion implantation process is about 0˜75 degrees.

5. The method of manufacturing the liquid crystal alignment film of claim 1, wherein after forming the material layer on the substrate and before performing the ion implantation process, the method further comprises etching back the material layer.

6. The method of manufacturing the liquid crystal alignment film of claim 1, wherein the steps of providing the material layer on the substrate comprise:
coating a layer of alignment material on the substrate by using a spin coating, a slit coating or a spin on dielectric (SOD) coating method; and
performing a baking process thereon.

7. The method of manufacturing the liquid crystal alignment film of claim 6, wherein the alignment material comprises HSQ, MSQ, SiO₂ or TiO₂ solution.

8. The method of manufacturing the liquid crystal alignment film of claim 1, wherein the step of providing the material layer on the substrate comprises forming an alignment material layer on the substrate by using a printing method.

9. The method of manufacturing the liquid crystal alignment film of claim 8, wherein the material of the alignment material layer comprises the polyimide (PI) and polyamide (PA) family.

10. The method of manufacturing the liquid crystal alignment film of claim 1, wherein the step of providing the material layer on the substrate comprises depositing an alignment material layer on the substrate.

11. The method of manufacturing the liquid crystal alignment film of claim 10, wherein the method for depositing the alignment material layer comprises a sputtering process, an evaporation process, a CVD (Chemical Vapor Deposition) process or a PE-CVD (Plasma Enhanced-Chemical Vapor Deposition) process.

12. The method of manufacturing the liquid crystal alignment film of claim 10, wherein the alignment material layer comprises an oxide.

13. A method of manufacturing a liquid crystal alignment film, comprising:
forming a material layer on a substrate;
patterning the material layer to form a patterned material layer; and
performing an alignment treatment on the patterned material layer by using an ion implantation process.

14. The method of manufacturing the liquid crystal alignment film of claim 13, wherein the ion implantation process comprises using a chemical element with valence of 3 or 5.

15. The method of manufacturing the liquid crystal alignment film of claim 13, wherein the ion implantation process comprises using a chemical element such as B (boron), P (phosphorus), As (arsenic) or Sb (antimony).

16. The method of manufacturing the liquid crystal alignment film of claim 13, wherein the implanting angle of the ion implantation process is about 0˜75 degrees.

17. The method of manufacturing the liquid crystal alignment film of claim 13, wherein after patterning the material layer and before performing the ion implantation process, the method further comprises etching back the patterned material layer.

18. The method of manufacturing the liquid crystal alignment film of claim 13, wherein the step of patterning the material layer comprises performing a photoresist process, a coating process, an exposure process, a development process, an etching process and a stripping process.

19. The method of manufacturing the liquid crystal alignment film of claim 13, wherein the steps of forming the material layer on the substrate comprise:
coating a layer of alignment material on the substrate by using a spin coating, a slit coating or a spin on dielectric (SOD) coating method; and
performing a baking process thereon.

20. The method of manufacturing the liquid crystal alignment film of claim 19, wherein the alignment material comprises HSQ, MSQ, SiO₂ or TiO₂ solution.

21. The method of manufacturing the liquid crystal alignment film of claim 13, wherein the step of forming the material layer on the substrate comprises depositing an alignment material layer on the substrate.

22. The method of manufacturing the liquid crystal alignment film of claim 21, wherein the method for depositing the alignment material layer comprises a sputtering process, an evaporation process, a CVD (Chemical Vapor Deposition) process or a PE-CVD (Plasma Enhanced-Chemical Vapor Deposition) process.

23. The method of manufacturing the liquid crystal alignment film of claim 21, wherein the alignment material layer comprises an oxide.
